(19) United States
(12) Patent Application Publication
(10) Pub. No.: US 2004/0169500 A1
(43) Pub. Date: Sep. 2, 2004

(54) Kilowatt-hour Counter Using An ADI ADE7755

(75) Inventor: Johnnyson P. Jones, Alexandria, VA (US)

Correspondence Address: JOHNNYSON PLATO JONES II, 7432 GRUMMAN PLACE, ALEXANDRIA, VA, 22306, US

(73) Assignee: Mr. Johnnyson Plato Jones JR., Alexandria, VA (US)

(21) Appl. No.: 10/248,918

(22) Filed: Mar. 1, 2003

(51) Int. Cl. G01R 11/32

(52) U.S. Cl. 324/142

(57) ABSTRACT

A kilowatt-hour counter (10) is provided that accepts the male plug of a standard US household appliance and that is plugged into a standard US household electrical socket. An extremely low ohm resistor is used to create a voltage proportional to the electrical energy used. This voltage is used by an Analog Devices Energy Monitoring Integrated Chip, along with a Microchip Corporation microprocessor, to produce and display a kilowatt-hour count. Two alternate embodiments are presented. In the first, the kilowatt-hour counter is mounted behind a standard 2-female outlet (20). In the second, the kilowatt-hour counter is mounted behind a standard 1-switch wall switch (30).

### BACKGROUND OF INVENTION

As energy costs increase, consumers are finding it necessary to monitor and to control the energy usage of household appliances. A useful invention is one that provides accurate energy usage information and is easy and convenient to use.

There are a number of techniques to monitor the kilowatt-hours used by electrical equipment but very few for US household appliances. In addition, most techniques require the monitor product inventor to use a microcomputer and develop software to calculate energy usage. These techniques increase development costs and market price.

The Analog Devices, Inc. integrated circuit product, AD7755, is designed specifically to measure and count kilowatt-hours of a monitored device. The Analog Devices. Inc. ADE7755 is the next generation of the AD7755 and is pin-compatible. The term “ADE7755” will be used to refer to both the ADE7755 and AD7755.

This invention uses the ADE7755 to implement a kilowatt-hour counter for household appliances. The Analog Devices, Inc. Application Note AN-559 details the configuration of the ADE7755 for use as a kilowatt-hour counter. Previous techniques for implementing kilowatt-hour meters used a microprocessor to directly monitor the instantaneous power consumption and to compute the kilowatt-hours used. The ADE7755 greatly reduces the complexity of design and implementation, and as a result, the cost of the meter is reduced.

It is the object of the present invention to provide a low-cost kilowatt-hour counter for US household appliances.

### SUMMARY OF INVENTION

The object of this present invention is to provide a kilowatt-hour meter using an Analog Devices, Inc. ADE7755 and a Microchip Corporation, PIC16C620A microprocessor for measuring the electrical energy used by a common US household device. The kilowatt-hours used by the device is displayed on a four digit LED character display.

This invention is enabled by the functionality of the ADE7755. The ADE7755 uses as inputs a calibrating signal and a signal proportional to the energy consumption of the monitored US household device (referred to as the input signal) and outputs a pulse train with frequency proportional to the consumed kilowatt-hours.

The operation of the ADE7755 is well documented by Analog Devices, Inc. This invention uses the operational configuration as documented by Analog Devices, Inc. Application Note AN-559. In this configuration, a very low ohm resistor is used as a sense resistor, producing a voltage referred to as the input signal.

A calibrating signal is produced by reducing the line voltage down to a voltage that produces the required meter accuracy.

The meter consists of a 2 piece plastic enclosure with a standard 3-prong male plug in the back of the enclosure and a standard 3-prong female plug in the front of the enclosure. Also on the front of the enclosure, there is a 4-digit LED character display. There are two printed circuit boards: one for the main processing of the meter and one for the LED display.

There are two other embodiments of the invention. For Alternative Embodiment 1, the meter's electronics are mounted behind a standard US 2-female outlet plug. The LED display is mounted in the associated faceplate.

For Alternative Embodiment 2, the meter's electronics are mounted behind a standard US single wall switch. The LED display is mounted in the associated faceplate.

### BRIEF DESCRIPTION OF DRAWINGS

FIGS. 1A to 1D are the front, side, top and rear views of a kilowatt-hour counter according to one embodiment of the invention.

FIG. 2 is a schematic of the electrical circuit of the counter of FIG. 1.

FIG. 3 is the front view of a counter according to Alternate Embodiment 1 of the invention.

FIG. 4 is the front view of a counter according to Alternate Embodiment 2 of the invention.

### DETAILED DESCRIPTION

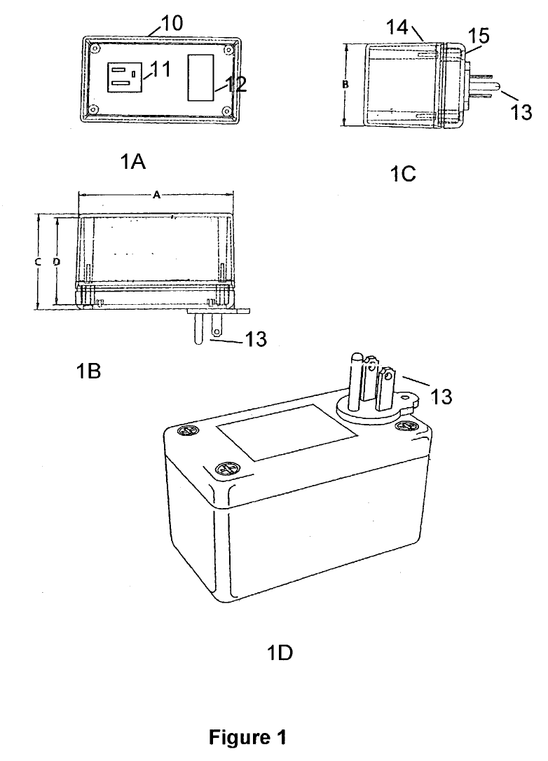

Referring to FIGS. 1A to 1D, Reference number (10) uses the ADE7755 to implement a kilowatt-hour counter for household appliances. A standard US 110VAC 60 Hz household appliance is plugged into the female receptacle (11). The meter is plugged into a standard US 110VAC 60 Hz wall socket via male plugs (13).

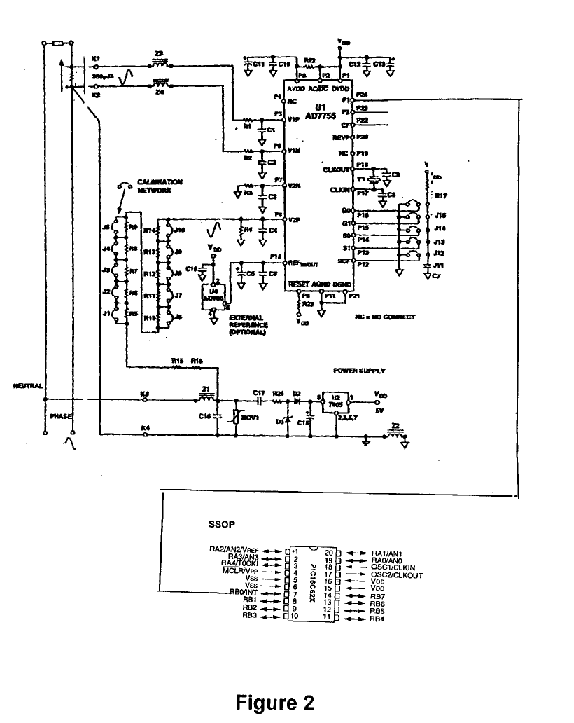

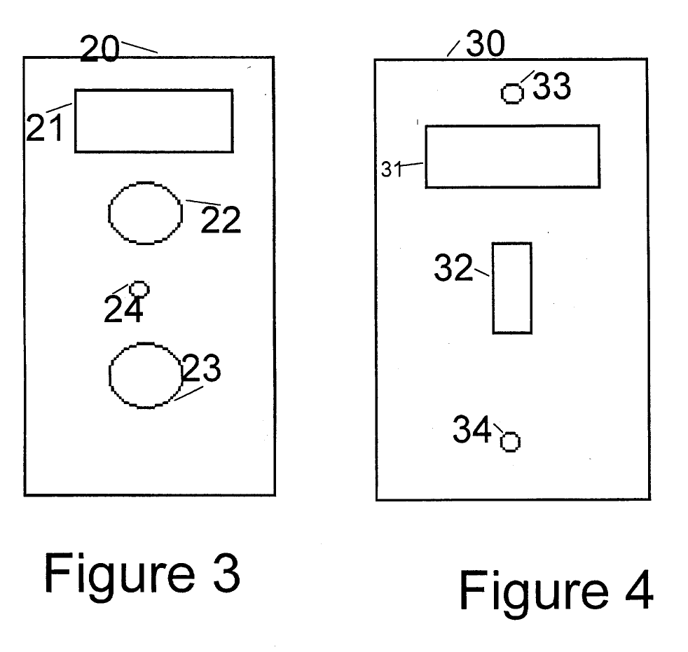

Referring to FIG. 2, the hot (phase) side of receptacle (11) is connected to a 350 microOhm resistor (Rshunt) which is connected to the hot side of the male receptacle (24). This resistor induces a small AC voltage that is the input to Channel 1 (Pins VIP and VIN) of the Analog Device, Inc. ADE7755.

The meter (10) is calibrated at the base current of 5 Amps. The maximum current is 40 Amps. At 40 Amps, the maximum frequency of the output pulse train is set to 3.4 Hz by enabling pins S1 and S0 of the ADE7755 to logic high. The Channel 1 input voltage gain is set to 16 by enabling pins G0 and G1 of the ADE7755 to logic high.

The line voltage, 110VAC, is attenuated down to 132 mVAC and is the input to Channel 2 (Pins V2P and V2N) of the ADE7755. This voltage, 132 mVAC, is selected to calibrate the ADE7755 for the design current range of up to 40 Amps.

The ADE7755 uses the voltages on Channel 1 and Channel 2, along with the ADE7755 configuration inputs to produce an output pulse train on pin F1 of the ADE7755 with frequency determined by:

output frequency=(8.06*(voltage on Channel 1)*(voltage on Channel 2)*16* 3.4)/6.25

Pin F1 of the ADE7755 is connected to Pin RB0/INT of the Microchip Technology, Inc PIC16C620A microprocessor. The PIC16C620 has 512 bytes of EPROM memory. The ADE7755, when properly configured, produces 100 pulses for each kilowatt-hour of energy consumed by the monitored appliance. The Interrupt Service Routine for the RB0/INT pin counts each pulse. After 10 pulses, a flag is set for the main program to increment the count. The PIC16C620A displays the count (which is the kilowatt-hours to the nearest tenth) on the 0.28 inch , 4-digit, 7-segment Common Anode LED display.

DC power is derived from the 110VAC line voltage. Referring to FIG. 2, the line voltage is filtered for high frequency transients using bead core Z1, Capacitors C16 and C17 and varistor MOV1. Network components resistor R21, diode D2, Zener Diode D3, and Capacitor C18 provide a suitable input voltage for the Voltage Regulator IC, U2. The DC supply voltage is 5 VDC.

The monitor is implemented on two Printed Circuit Boards (PCB). The main PCB implements the ADE7755 monitoring and the PIC16C620A processing and display control functions. The Input/output (I/O) PCB implements the LED display (12). The main PCB is mounted into Enclosure (15). The I/O PCB is mounted into Enclosure (14). Female receptacle (11) is inserted into Enclosure (14). The main PCB is connected to the I/O PCB by ribbon cable. The main PCB is connected to the male receptacle (13) and the female receptacle (11) using 22 gauge copper wire.

In Alternative Embodiment 1, the main PCB board is mounted to the rear of the modified US 2-female plug wall outlet. The I/O PCB is mounted in the faceplate (20) of the modified US 2-female plug outlet. The 2-female wall outlet (not shown) is attached to the rear of the faceplate.

In Alternative Embodiment 2, The main PCB board is mounted to the rear of the modified US single switch unit. The I/O PCB is mounted in the faceplate (30) of the modified US single outlet. The single switch outlet unit (not shown) is attached to the rear of the faceplate.

What is claimed is:

1. An electric kilowatt-hour counter comprising:
a body member;
An Analog Devices, Inc. ADE7755 Energy Measurement IC for measuring the voltage of the monitored device and producing a pulse train with frequency proportional to the kilowatt-hours consumed;
A Microchip Corporation PIC16C620A Microprocessor IC for monitoring and counting the pulse train and for converting the pulse train count into the corresponding kilowatt-hour count;
A display system consisting of a 4 digit LED display for outputting the kilowatt-hour count;
A low ohm resistor for producing a voltage proportional to the electrical energy used.
PIC16C620 Assembly language program controlling the PIC16C620 operations Prongs on the body member for insertion into an electric wall socket;
A female socket on the body member for receiving the plug of an electric appliance, said socket being in electrical communication with the prongs for transferring electric power from the prongs to said socket;
